(19) United States
(12) Patent Application Publication
(10) Pub. No.: US 2009/0104560 A1
(43) Pub. Date: Apr. 23, 2009

(54) BARRIER FILM MATERIAL AND PATTERN FORMATION METHOD

(76) Inventors: Masayuki ENDO, Osaka (JP); Masaru Sasago, Osaka (JP)

Correspondence Address: MCDERMOTT WILL & EMERY LLP, 600 13TH STREET, NW, WASHINGTON, DC, 20005-3096, US

(21) Appl. No.: 12/202,615

(22) Filed: Sep. 2, 2008

(30) Foreign Application Priority Data
Oct. 17, 2007 (JP) 2007-269748

(51) Int. Cl. G03F 7/004; G03F 7/20

(52) U.S. Cl. 430/270.1; 430/326

(57) ABSTRACT

In exposing a resist film to light with a liquid provided on a positive chemically amplified resist film, a barrier film material for a barrier film formed between the resist film and the liquid includes a compound having an acid leaving group and a thermal acid generator.

### CROSS-REFERENCE TO RELATED APPLICATION

The disclosure of Japanese Patent Application No. 2007-269748 filed on Oct. 17, 2007 including specification, drawings and claims is incorporated herein by reference in its entirety.

### BACKGROUND OF THE INVENTION

The present invention relates to a material for a barrier film formed on a resist film and a pattern formation method for use in, for example, fabrication of a semiconductor device.

In accordance with the increased degree of integration of semiconductor integrated circuits and downsizing of semiconductor devices, there are increasing demands for further rapid development of lithography technique. Currently, pattern formation is carried out through photolithography using, for exposure light, a light source such as a mercury lamp, a KrF excimer laser, or an ArF excimer laser. Use of an F₂ laser with a shorter wavelength was also examined, but development thereof is now stopped because there remain a large number of problems in exposure systems and resist materials.

In these circumstances, immersion lithography has been recently proposed to achieve further reduction in pattern size by using conventional exposure light (see, for example, M. Switkes and M. Rothschild, “Immersion lithography at 157 nm”, J. Vac. Sci. Technol., Vol. B19, p. 2353 (2001)).

In the immersion lithography, a region in an exposure system sandwiched between a projection lens and a resist film formed on a wafer is filled with a liquid (immersion liquid) having a refractive index of n (where n>1) and, therefore, the NA (numerical aperture) of the exposure system has a value of n·NA. As a result, the resolution of the resist film is enhanced. In addition, to further increase the refractive index of the liquid, the use of an acid solution as an immersion solution is proposed. (see, for example, B. W. Smith, A. Bourov, Y. Fan, L. Zavyalova, N. Lafferty, F. Cropanese, “Approaching the numerical aperture of wafer—Immersion lithography at 193 nm”, Proc. SPIE, Vol. 5377, p. 273 (2004).).

Now, a conventional pattern formation method employing immersion lithography will be described with reference to FIGS. 7A through 7D.

First, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethanesulfonic | 0.05 | g |
| acid | | |
| Quencher: triethanolamine | 0.002 | g |
| Solvent: propylene glycol monomethyl ether acetate | 20 | g |

Next, as shown in FIG. 7A, the aforementioned resist material is applied on a substrate 1 to form a resist film 2 with a thickness of 0.35 μm.

Then, as shown in FIG. 7B, with an immersion liquid 3 of water provided on the resist film 2 by, for example, a puddle method, pattern exposure is carried out by irradiating the resist film 2 with exposure light 5, which is ArF excimer laser light with an NA of 0.68, through a mask 4.

After the pattern exposure, as shown in FIG. 7C, the resist film 2 is baked with a hot plate at a temperature of 105° C. for 60 seconds (post exposure bake).

Thereafter, the resultant resist film is developed with a 2.38 wt % tetramethylammonium hydroxide aqueous solution (alkaline developer), thereby obtaining a resist pattern 2a made of an unexposed part of the resist film 2 and having a line width of 0.09 μm, as shown in FIG. 7D.

### SUMMARY OF THE INVENTION

The present inventors found a phenomenon in which the resist pattern 2a obtained by the foregoing conventional pattern formation method has residues (i.e., substances remaining undissolved) 2b of, for example, an altered material produced by contact between the resist film 2 and the immersion liquid 3, as shown in FIG. 7D. When a target film is etched using the resist pattern 2a having such residues 2b, the resultant pattern fails to have a desired shape, thus reducing productivity and yield in fabrication processes of a semiconductor device.

In the case of providing a barrier film on the resist film, the barrier film and an immersion liquid are in contact with each other, producing residues (i.e., substances remaining undissolved) of, for example, an altered material resultant from direct contact between the barrier film and the resist film. Then, the same problems as described above also arise.

It is therefore an object of the present invention to obtain a fine pattern with a desired shape by eliminating residues (i.e., substances remaining undissolved) after development of a positive resist with immersion lithography.

The present inventors have conducted various examinations to find that defect-causing materials (residues) produced in a pattern after development are removed by making the surface of a resist film (i.e., a positive chemically amplified resist) after pattern exposure alkali-soluble and performing development after the exposure to dissolve a surface portion of an unexposed part of the resist film as well as an exposed part thereof.

To make the surface of the resist film alkali-soluble, techniques including a first technique of processing the surface of the resist film with a solution containing a thermal acid generator and then heating the resultant resist film and a second technique of forming a barrier film containing a compound having an acid leaving group and a thermal acid generator on the resist film are employed.

A thermal acid generator generates an acid when heated, and the acid moves in a resist film. In the resist film, since the acid moves from the surface of the resist, the acid is first diffused in a surface portion of the resist. Then, the acid reacts with an acid leaving group in the resist film to make this acid leaving group alkali-soluble. Accordingly, the surface portion of the resist including its unexposed part is dissolved in an alkaline developer in subsequent development. As a result, residues (i.e., substances remaining undissolved) of, for example, an altered material produced by contact between a liquid for immersion lithography and the resist film are removed during the development.

In the barrier film, an acid generated by heat reacts with an acid leaving group in the barrier film and the acid leaving group in the surface portion of the resist film which is in contact with the barrier film, so that these acid leaving groups which have reacted with the acid become alkali-soluble. Accordingly, in subsequent development, solubility of the barrier film is improved and the surface portion of the resist film including its unexposed part is dissolved in an alkaline developer. As a result, the resist film and residues (i.e., substances remaining undissolved) of the barrier film are removed during the development. The barrier function of the barrier film between the immersion liquid and the resist film depends on the properties of a polymer constituting the barrier film. Thus, the addition of the compound having the acid leaving group and the thermal acid generator does not cause film properties to deteriorate.

The region to be alkali-soluble is preferably to a depth of about 10 nm or less, and more preferably to a depth of about 5 nm or less, in the surface portion of the resist film.

A dip method, a spray method and a puddle method, for example, can be employed as a surface process with a solution containing a thermal acid generator according to the present invention. However, the present invention is not limited to these methods. The surface process time only needs to be about 120 seconds or less, and more preferably in the range from about 10 seconds, inclusive, to about 60 seconds, inclusive.

The present invention has been made based on the foregoing findings and specifically is implemented by the following constitution.

A barrier film material according to the present invention is a material for a barrier film formed between a positive chemically amplified resist film and a liquid in exposing the resist film to light with the liquid provided on the resist film and includes: a compound having an acid leaving group; and a thermal acid generator.

According to the present invention, the barrier film material for use in immersion lithography includes a compound having an acid leaving group and a thermal acid generator. Thus, an acid generated by heat reacts with the acid leaving group in the barrier film and an acid leaving group in a surface portion of the resist film which is in contact with the barrier film, so that these acid leaving groups which have reacted with the acid become alkali-soluble. Accordingly, during development, the barrier film and the surface portion of the resist film including an unexposed part are dissolved in an alkaline developer so that the barrier film and residues (i.e., substances remaining undissolved) of the resist film are removed. As a result, a fine pattern with a desired shape is formed out of the resist film.

In the barrier film material of the present invention, the acid leaving group may be one of a t-butyl group, a 2-ethoxyethyl group, an adamanthyl group, and a t-butyloxycarbonyl group. The barrier film material only needs to include a compound having one of these acid leaving groups. These acid leaving groups may be included in a polymer (base polymer) constituting the barrier film.

In the barrier film material of the present invention, the thermal acid generator may be sulfonic acid ester whose ester moiety is an unsubstituted alkyl group expressed by the following chemical formula:

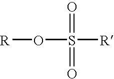

(where R is an unsubstituted alkyl group)

In this case, the sulfonic acid ester whose ester moiety is an unsubstituted alkyl group may be one of cyclohexylbenzenesulfonic acid, t-butylbenzene sulfonic acid, cyclohexyl toluenesulfonic acid, and t-butyltoluenesulfonic acid.

In the present invention, the concentration of the thermal acid generator in a solution used for a surface process of the resist film or the amount of addition of the thermal acid generator to the barrier film only needs to be at a level enough to cause a reaction of an acid leaving group in the resist film or the barrier film, i.e., about 20 wt % or less, and more preferably in the range from about 5 wt % to about 10 wt %, both inclusive.

As a polymer constituting the barrier film of the present invention, an alkali-soluble polymer such as polyvinyl alcohol, polyacrylic acid, or polyvinyl hexafluoroisopropyl alcohol may be used.

The barrier film of the present invention may be a stack of two or more layers and only needs to include a compound having an acid leaving group and a thermal acid generator at the bottom layer.

A first pattern formation method according to the present invention includes the steps of: forming a positive chemically amplified resist film on a substrate; performing pattern exposure by selectively irradiating the resist film with exposure light with a liquid provided on the resist film; performing a surface process for making the surface of the resist film alkali-soluble, after the pattern exposure; and developing the resist film subjected to the pattern exposure, thereby forming a resist pattern out of the resist film, after the surface process.

In the first pattern formation method, the surface process for making the surface of the resist film alkali-soluble is performed after the pattern exposure, so that a surface portion of the resist film including an unexposed part is dissolved in an alkaline developer in subsequent development. Accordingly, residues of, for example, an altered material produced by contact between an immersion liquid and the resist film are removed, thereby forming a fine pattern with a desired shape out of the resist film.

In the first pattern formation method, the step of performing the surface process preferably includes the steps of: exposing the resist film to a solution including a thermal acid generator; and heating the resist film exposed to the solution including the thermal acid generator.

Then, an acid generated by heat reacts with an acid leaving group in a surface portion of the resist film, so that the acid leaving group which has reacted with the acid becomes alkali-soluble. Accordingly, the surface of the resist film is made alkali-soluble.

A second pattern formation method according to the present invention includes the steps of: forming a positive chemically amplified resist film on a substrate; forming a barrier film including a compound having an acid leaving group and a thermal acid generator, on the resist film; performing pattern exposure by selectively irradiating the resist film with exposure light through the barrier film with a liquid provided on the barrier film; heating the resist film and the barrier film, after the pattern exposure; removing the barrier film, after the step of heating the resist film and the barrier film; and developing the resist film from which the barrier film has been removed, thereby forming a resist pattern out of the resist film.

A third pattern formation method according to the present invention includes the steps of: forming a positive chemically amplified resist film on a substrate; forming a barrier film including a compound having an acid leaving group and a thermal acid generator, on the resist film; performing pattern exposure by selectively irradiating the resist film with exposure light through the barrier film with a liquid provided on the barrier film; heating the resist film and the barrier film, after the pattern exposure; and developing the resist film subjected to the pattern exposure, thereby removing the barrier film and forming a resist pattern out of the resist film, after the step of heating the resist film and the barrier film.

In the second or third pattern formation method, a barrier film including a compound having an acid leaving group and a thermal acid generator is formed on a resist film, and then the resist film and the barrier film are heated after pattern exposure. Accordingly, an acid generated by heat in the barrier film including the compound having the acid leaving group and the thermal acid generator reacts with the acid leaving group in the barrier film and an acid leaving group in a surface portion of the resist film which is in contact with the barrier film. These acid leaving groups which have reacted with the acid become alkali-soluble. Thus, in a development process, the surface portion of the resist film including an unexposed part is dissolved in an alkaline developer, thereby removing the barrier film and residues of the resist film during development. As a result, a fine pattern with a desired shape is formed out of the resist film.

The second pattern formation method and the third pattern formation method differ from each other in the following aspects. In the second pattern formation method, the barrier film on the resist film is removed before development, whereas the barrier film on the resist film is removed with a developer during development in the third pattern formation method. In the second pattern formation method, since the barrier film is removed before development, development proceeds as usual without any problem. On the other hand, in the third pattern formation method, since the barrier film is removed during development, solubility of the resist film is controllable, thus improving solubility of the resist.

In the second or third pattern formation method, the acid leaving group may be one of a t-butyl group, a 2-ethoxyethyl group, an adamanthyl group, and a t-butyloxycarbonyl group.

In the first through third pattern formation methods, the thermal acid generator may be sulfonic acid ester whose ester moiety is an unsubstituted alkyl group.

In this case, the sulfonic acid ester whose ester moiety is an unsubstituted alkyl group may be one of cyclohexylbenzenesulfonic acid, t-butylbenzene sulfonic acid, cyclohexyl toluenesulfonic acid, and t-butyltoluenesulfonic acid.

The second or third pattern formation method preferably further includes the step of heating the barrier film, between the step of forming the barrier film and the step of performing the pattern exposure.

Then, the denseness of the barrier film is enhanced, thus further increasing insolubility of the barrier film in the immersion liquid. Since excessive increase in denseness of the barrier film makes it difficult to remove the barrier film by dissolving, the heat process needs to be performed within an appropriate range. The heat process also needs to be performed under a temperature (i.e., about 110° C.) at which an acid is generated by a thermal acid generator, and is usually performed at about 90° C. However, the heat process of the present invention is not limited to this temperature range.

In the first through third pattern formation methods, the liquid may be one of water and an acid solution.

In this case, the acid solution may be one of a cesium sulfate aqueous solution and a phosphoric acid aqueous solution. The immersion liquid may contain an additive such as a surface active agent.

In the first through third pattern formation methods, the exposure light may be one of ArF excimer laser light, KrF excimer laser light, Xe₂ laser light, F₂ laser light, KrAr laser light, and Ar₂ laser light.

As described above, a barrier film material and a pattern formation method according to the present invention eliminate residues of a resist produced during development by immersion lithography, resulting in obtaining a fine pattern with a desired shape.

### BRIEF DESCRIPTION OF THE DRAWINGS

FIGS. 1A through 1D are cross-sectional views illustrating respective process steps of a pattern formation method according to a first embodiment of the present invention.

FIG. 2 is a cross-sectional view illustrating a process step of the pattern formation method of the first embodiment.

FIGS. 3A through 3D are cross-sectional views illustrating respective process steps of a pattern formation method using a barrier film material according to a second embodiment of the present invention.

FIGS. 4A through 4C are cross-sectional views illustrating respective process steps of the pattern formation method using the barrier film material of the second embodiment.

FIGS. 5A through 5D are cross-sectional views illustrating respective process steps of a pattern formation method using a barrier film material according to a third embodiment of the present invention.

FIGS. 6A and 6B are cross-sectional views illustrating respective process steps of the pattern formation method using the barrier film material of the third embodiment.

FIGS. 7A through 7D are cross-sectional views illustrating respective process steps of a conventional pattern formation method.

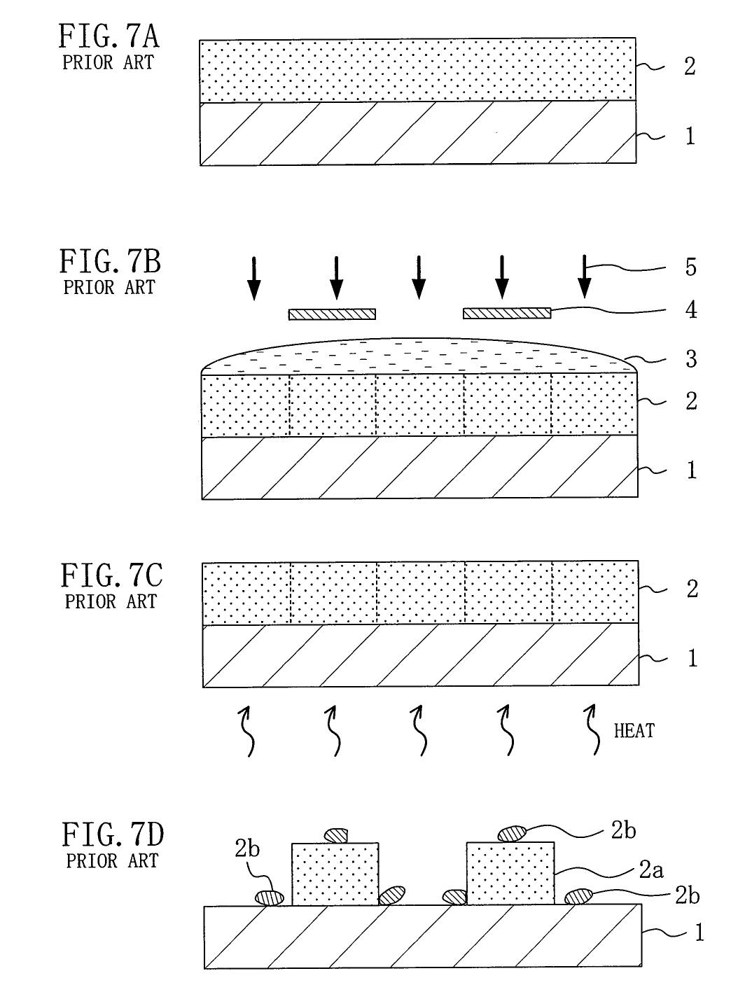

### DETAILED DESCRIPTION OF THE INVENTION

### Embodiment 1

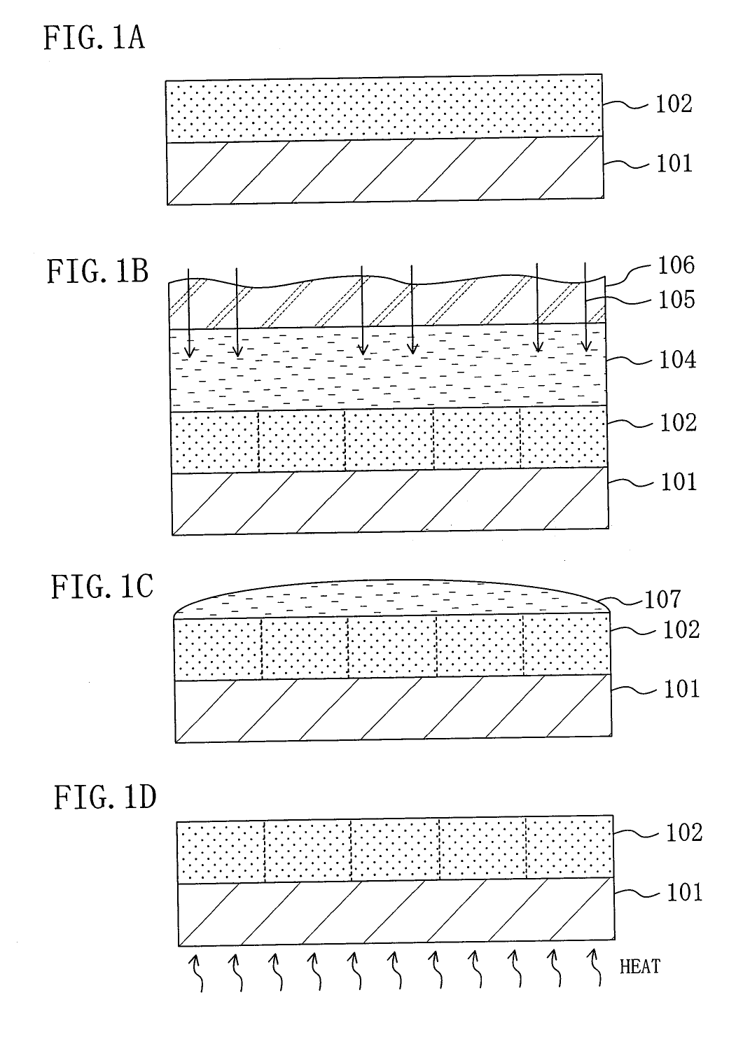

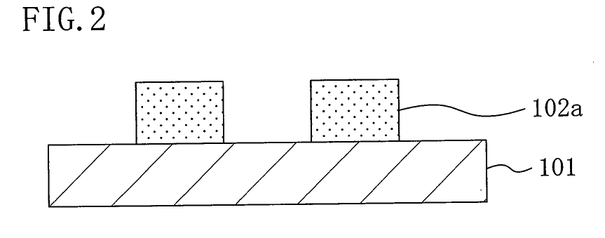

A pattern formation method using a barrier film material according to a first embodiment of the present invention will be described with reference to FIGS. 1A through 1D and 2.

First, for example, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethanesulfonic | 0.05 | g |
| acid | | |
| Quencher: triethanolamine | 0.002 | g |
| Solvent: propylene glycol monomethyl ether acetate | 20 | g |

Next, as shown in FIG. 1A, the aforementioned resist material is applied on a substrate 101 to form a resist film 102 with a thickness of, for example, 0.35 μm.

Next, as shown in FIG. 1B, with an immersion liquid 104 of water provided between the resist film 102 and a projection lens 106 by, for example, a puddle method, pattern exposure is carried out by irradiating the resist film 102 with exposure light 105, which is ArF excimer laser light with an NA of 0.68, through a mask (not shown).

Then, as shown in FIG. 1C, a dip process in which the resist film 102 is dipped for 20 seconds in a sec-butyl alcohol solution 107 to which 7 wt % cyclohexylbenzenesulfonic acid as a thermal acid generator is added is carried out.

After the pattern exposure and the dip process, as shown in FIG. 1D, the resist film 102 is baked with a hot plate at a temperature of 105° C. for 60 seconds (post exposure bake).

Thereafter, the baked resist film 102 is developed with a 2.38 wt % tetramethylammonium hydroxide aqueous solution (alkaline developer), thereby obtaining a resist pattern 102a which is made of an unexposed part of the resist film 102 and has a desired shape with a line width of 0.09 μm, as shown in FIG. 2.

In this manner, in the dip process of the first embodiment shown in FIG. 1C, the surface of the resist film 102 of a positive chemically amplified resist is dipped in the alcohol solution 107 containing cyclohexylbenzenesulfonic acid as a thermal acid generator. Accordingly, an acid is generated from the thermal acid generator attached to the surface of the resist film 102 in the heat process (post exposure bake) shown in FIG. 1D, and then is diffused in a surface portion of the resist film 102. The diffused acid reacts with an acid leaving group in the resist film 102 so that the acid leaving group which has reacted with the acid becomes alkali-soluble. Accordingly, in the development process shown in FIG. 2, a region to a depth of about 5 nm in the surface portion of the resist film 102 including the unexposed part is dissolved in the alkaline developer, so that residues of, for example, an altered material produced by contact between the immersion liquid 104 and the resist film 102 are removed during the development process, thus obtaining a desired pattern shape of the resist pattern 102a.

In the first embodiment, the region to a depth of about 5 nm in the surface portion of the resist film 102 is dissolved in the alkaline developer. Alternatively, the depth of the region in the surface portion of the resist film 102 dissolved in the developer may be appropriately adjusted depending on the concentration of the solution containing the thermal acid generator, the dip time, the bake temperature and bake time in the heat process, the development time, and other factors.

In the first embodiment, cyclohexylbenzenesulfonic acid is used as sulfonic acid ester whose ester moiety is an unsubstituted alkyl group and which is a thermal acid generator used in the dip process. Alternatively, t-butylbenzene sulfonic acid, cyclohexyl toluenesulfonic acid, or t-butyltoluenesulfonic acid, for example, may be used.

### Embodiment 2

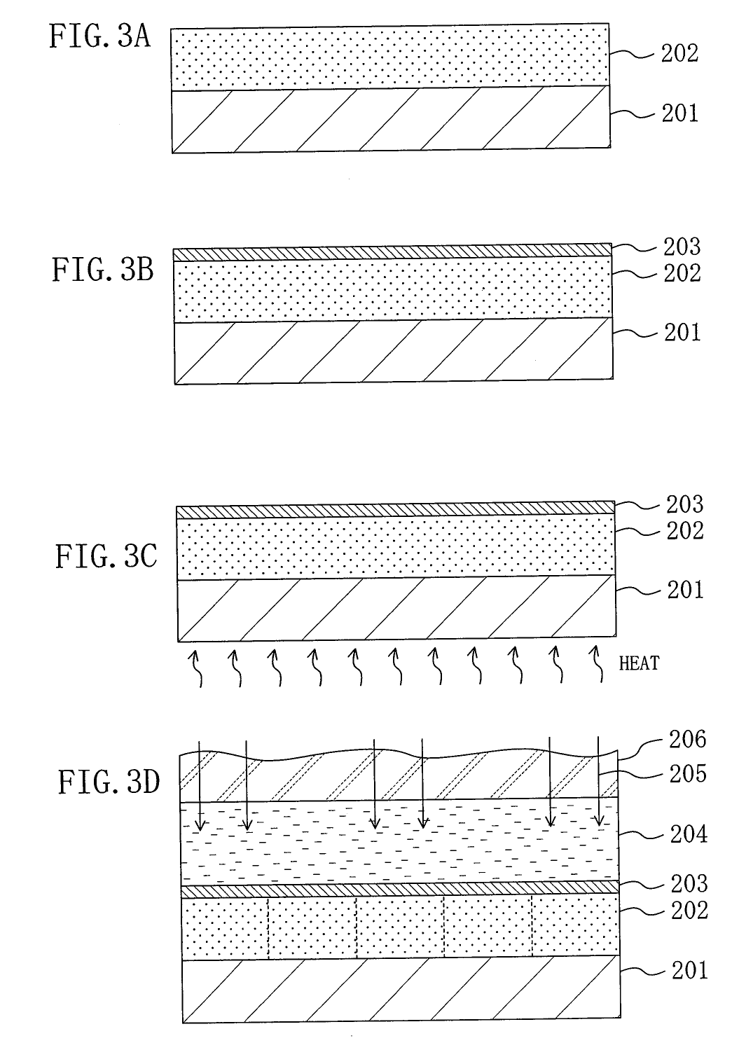

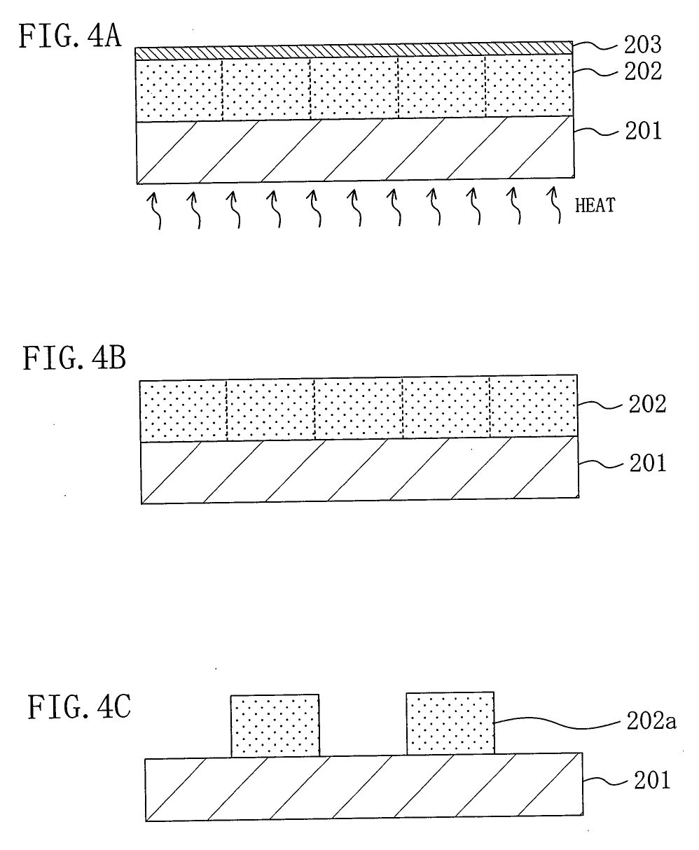

Now, a pattern formation method using a barrier film material according to a second embodiment of the present invention will be described with reference to FIGS. 3A through 3D and 4A through 4C.

First, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethanesulfonic | 0.05 | g |
| acid | | |
| Quencher: triethanolamine | 0.002 | g |
| Solvent: propylene glycol monomethyl ether acetate | 20 | g |

Next, as shown in FIG. 3A, the aforementioned resist material is applied on a substrate 201 to form a resist film 202 with a thickness of 0.35 μm.

Then, as shown in FIG. 3B, a barrier film 203 which is made of a barrier film material having the following composition and has a thickness of 0.07 μm is formed on the resist film 202 by, for example, spin coating:

| | |
|---|---|
| Base polymer: polyvinyl hexafluoroisopropyl alcohol | 1 g |
| Compound having acid leaving group: adamanthyl methacrylate | 0.3 g |
| Thermal acid generator: t-butylbenzene sulfonic acid | 0.1 g |
| Solvent: n-butyl alcohol | 20 g |

Thereafter, as shown in FIG. 3C, the barrier film 203 is heated with a hot plate at a temperature of 90° C. for 60 seconds, thereby increasing the denseness of the barrier film 203.

Then, as shown in FIG. 3D, with an immersion liquid 204 of water provided between the barrier film 203 and a projection lens 206 by, for example, a puddle method, pattern exposure is carried out by irradiating the resist film 202 through the barrier film 203 with exposure light 205, which is ArF excimer laser light with an NA of 0.68, through a mask (not shown).

After the pattern exposure, as shown in FIG. 4A, the resist film 202 is baked with a hot plate at a temperature of 115° C. for 60 seconds (post exposure bake).

Thereafter, as shown in FIG. 4B, the barrier film 203 is removed with a 0.05 wt % tetramethylammonium hydroxide aqueous solution (alkaline diluted developer), and then the baked resist film 202 is developed with a 2.38 wt % tetramethylammonium hydroxide aqueous solution (alkaline developer). As a result, a resist pattern 202a which is made of an unexposed part of the resist film 202 and has a desired shape with a line width of 0.09 μm is obtained, as shown in FIG. 4C.

In this manner, in the second embodiment, before the pattern exposure shown in FIG. 3D, the barrier film 203 including the compound having the acid leaving group (adamanthyl methacrylate) and the thermal acid generator (t-butylbenzene sulfonic acid) is formed on the resist film 202. Accordingly, in the heat (post exposure bake) process shown in FIG. 4A, an acid is generated by heat from the thermal acid generator in the barrier film 203, and then reacts with the acid leaving group in the barrier film 203 and an acid leaving group in a surface portion of the resist film 202 which is in contact with the barrier film 203, so that these acid leaving groups which have reacted with the acid become alkali-soluble. Thus, in subsequent development, solubility of the barrier film 203 is improved and a region to a depth of about 3 nm in the surface portion of the resist film 202 including the unexposed part is dissolved in the alkaline developer. As a result, the barrier film 203 and residues of the resist film 202 are removed during the development.

In the second embodiment, the region to a depth of about 3 nm in the surface portion of the resist film 202 is dissolved in the alkaline developer. Alternatively, the depth of the region in the surface portion of the resist film 202 dissolved in the developer may be appropriately adjusted depending on the concentration of the compound containing the thermal acid generator and the acid leaving group in the barrier film 203, the bake time and bake temperature in the post exposure bake, the development time, and other factors.

In the second embodiment, as shown in FIG. 3C, the barrier film 203 is heated to enhance the denseness thereof before pattern exposure, thereby increasing the insolubility of the barrier film 203 in the immersion liquid 204. Accordingly, the function of the barrier film 203 as a barrier for preventing elution of the acid generator or the like from the resist film 202 into the immersion liquid 204 is improved. As described above, the temperature in the heat process for enhancing the denseness is, of course, at a level at which no acid is generated from the thermal acid generator. The heat process for increasing the denseness of the barrier film 203 may not be performed.

In the second embodiment, t-butylbenzene sulfonic acid is used as sulfonic acid ester whose ester moiety is an unsubstituted alkyl group and which is a thermal acid generator to be added to the barrier film 203. Alternatively, cyclohexylbenzenesulfonic acid, cyclohexyl toluenesulfonic acid, or t-butyltoluenesulfonic acid, for example, may be used.

In the second embodiment, adamanthyl methacrylate is used as the compound containing the acid leaving group to be added to the barrier film 203. Alternatively, a t-butyl group, a 2-ethoxyethyl group, or a t-butyloxycarbonyl group may be used as an acid leaving group.

### Embodiment 3

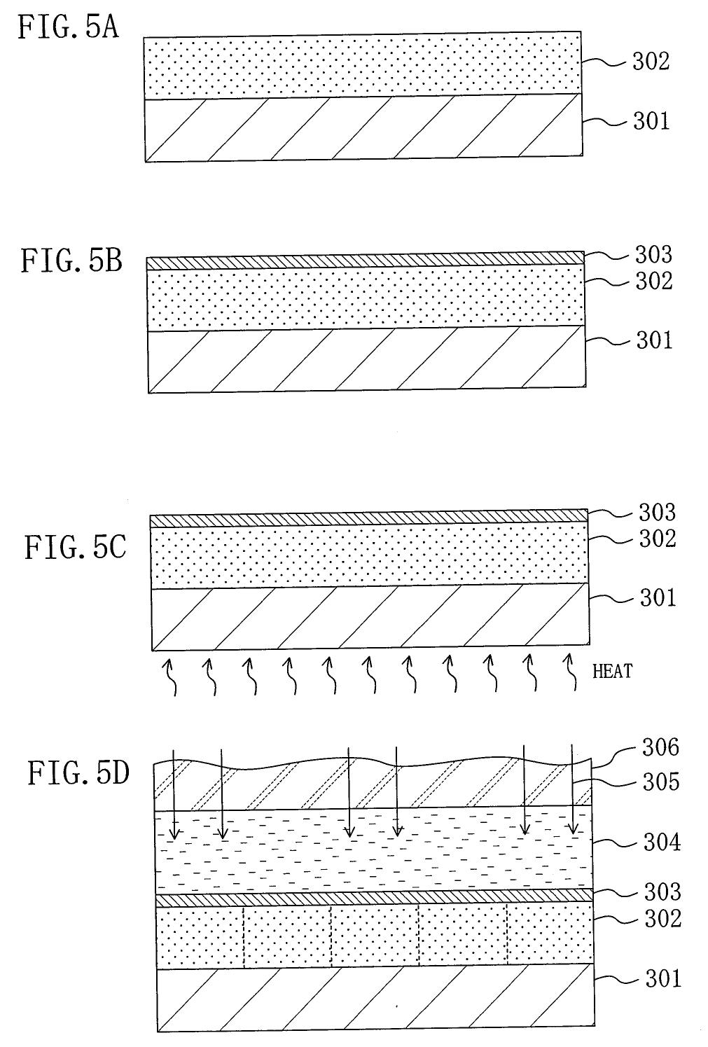

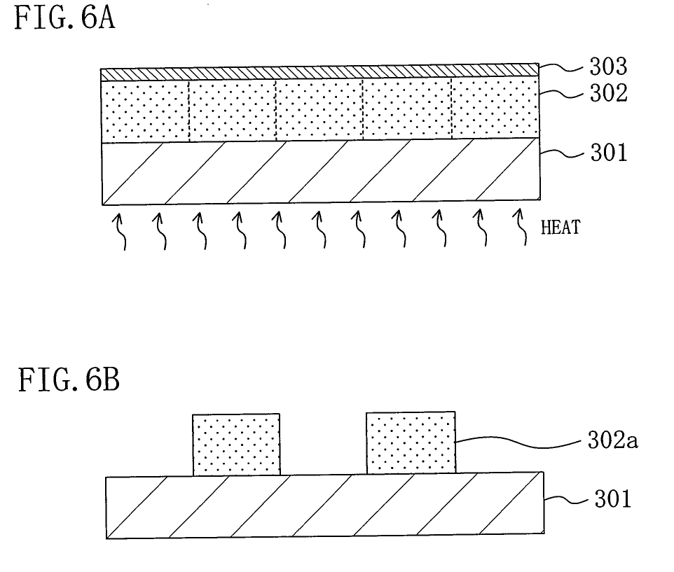

Now, a pattern formation method using a barrier film material according to a third embodiment of the present invention will be described with reference to FIGS. 5A through 5D, 6A, and 6B.

First, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethanesulfonic | 0.05 | g |
| acid | | |
| Quencher: triethanolamine | 0.002 | g |
| Solvent: propylene glycol monomethyl ether acetate | 20 | g |

Next, as shown in FIG. 5A, the aforementioned resist material is applied on a substrate 301 to form a resist film 302 with a thickness of 0.35 μm.

Then, as shown in FIG. 5B, a barrier film 303 which is made of a barrier film material having the following composition and has a thickness of 0.10 μm is formed on the resist film 302 by, for example, spin coating:

| | | |
|---|---|---|
| Base polymer: polyacrylic acid | 1 | g |
| Compound having acid leaving group: t-butyl acrylic acid | 0.8 | g |
| Thermal acid generator: cyclohexyl toluenesulfonic acid | 0.12 | g |
| Solvent: n-butyl alcohol | 20 | g |

Thereafter, as shown in FIG. 5C, the barrier film 303 is heated with a hot plate at a temperature of 90° C. for 60 seconds, thereby increasing the denseness of the barrier film 303.

Then, as shown in FIG. 5D, with an immersion liquid 304 of water provided between the barrier film 303 and a projection lens 306 by, for example, a puddle method, pattern exposure is carried out by irradiating the resist film 302 through the barrier film 303 with exposure light 305, which is ArF excimer laser light with an NA of 0.68, using a mask (not shown).

After the pattern exposure, as shown in FIG. 6A, the resist film 302 is baked with a hot plate at a temperature of 115° C. for 60 seconds (post exposure bake).

Thereafter, the barrier film 303 is removed with a 2.38 wt % tetramethylammonium hydroxide aqueous solution (alkaline developer), and the baked resist film 302 is further developed. As a result, as shown in FIG. 6B, a resist pattern 302a which is made of an unexposed part of the resist film 302 and has a desired shape with a line width of 0.09 μm is obtained.

In this manner, in the third embodiment, before the pattern exposure shown in FIG. 5D, the barrier film 303 including the compound having the acid leaving group (t-butyl acrylic acid) and the thermal acid generator (cyclohexyl toluenesulfonic acid) is formed on the resist film 302. Accordingly, in the heat (post exposure bake) process shown in FIG. 6A, an acid is generated by heat from the thermal acid generator in the barrier film 303, and then reacts with the acid leaving group in the barrier film 303 and an acid leaving group in a surface portion of the resist film 302 which is in contact with the barrier film 303, so that these acid leaving groups which have reacted with the acid become alkali-soluble. Thus, in subsequent development, solubility of the barrier film 303 is improved and a region to a depth of about 2 nm in the surface portion of the resist film 302 including the unexposed part is dissolved in the alkaline developer. As a result, the barrier film 303 and residues of the resist film 302 are removed during the development.

In the third embodiment, the region to a depth of about 2 nm in the surface portion of the resist film 302 is dissolved in the alkaline developer. Alternatively, the depth of the region in the surface portion of the resist film 302 dissolved in the developer may be appropriately adjusted depending on the concentration of the compound containing the thermal acid generator and the acid leaving group in the barrier film 303, the bake temperature and bake time in the post exposure bake, the development time, and other factors.

In the third embodiment, as shown in FIG. 5C, the barrier film 303 is heated to enhance the denseness thereof before the pattern exposure, thereby increasing the insolubility of the barrier film 303 in the immersion liquid 304. Accordingly, the function of the barrier film 303 as a barrier for preventing elution of the acid generator or the like from the resist film 302 into the immersion liquid 304 is improved. As described above, the temperature in the heat process for increasing the denseness is, of course, at a level at which no acid is generated from the thermal acid generator. The heat process for increasing the denseness of the barrier film 303 may not be performed.

In the third embodiment, cyclohexyl toluenesulfonic acid is used as sulfonic acid ester whose ester moiety is an unsubstituted alkyl group and which is a thermal acid generator to be added to the barrier film 303. Alternatively, cyclohexylbenzenesulfonic acid, t-butylbenzene sulfonic acid, or t-butyltoluenesulfonic acid, for example, may be used.

In the third embodiment, t-butyl acrylic acid is used as the compound containing the acid leaving group to be added to the barrier film 303. Alternatively, a 2-ethoxyethyl group, an adamanthyl group, or a t-butyloxycarbonyl group may be used as an acid leaving group.

In the pattern formation methods of the first through third embodiments, water is used as an immersion liquid. Alternatively, an acid solution may be used. Examples of the acid solution include a cesium sulfate (Cs₂SO₄) aqueous solution and a phosphoric acid (H₃PO₄) aqueous solution. However, the present invention is not limited to these examples. In these cases, the concentration of cesium sulfate or phosphoric acid is in the range from about 1 wt % to about 10 wt %. However, the present invention is not limited to this range. The immersion liquid may contain an additive such as a surface active agent.

The thickness of the barrier films of the present invention is not limited to the range from about 0.07 μm to about 0.10 μm, described in the second and third embodiments, and have a minimum value enough to prevent elution of an ingredient from the resist film into an immersion liquid or permeation of the immersion liquid into the resist film and a maximum value enough to allow the barrier film to be easily removed without preventing exposure light from passing therethrough. Specifically, the thickness of the barrier film is preferably in the range from 0.05 μm to 0.12 μm. However, the present invention is not limited to this range.

The depth of the alkali-soluble region in the surface portion of the resist film of the present invention is not limited to the depths described in the first through third embodiments. The depth only needs to be at a level enough to allow complete removal of the resist film or residues of the barrier film from the surface of the resist film with a developer, and is preferably about 10 nm or less. The thickness of the resist film after the development is preferably about 5 nm or less because the resistance during, for example, etching after pattern formation must be maintained. However, the present invention is not limited to these ranges.

In the pattern formation methods of the first through third embodiments, ArF excimer laser light is used as exposure light. Alternatively, KrF excimer laser light, Xe₂ laser light, F₂ laser light, KrAr laser light, or Ar₂ laser light may be used.

In the foregoing embodiments, a puddle method is employed to provide the immersion liquid on the barrier film. However, the present invention is not limited to this, and other methods such as a dip method in which the whole substrate is dipped into the immersion liquid may be employed.

The positive chemically amplified resist materials used in the foregoing embodiments are only examples, and the present invention is also effective with positive chemically amplified resists having other compositions.

As described above, a barrier film material and a pattern formation method according to the present invention eliminate residues (i.e., substances remaining undissolved) produced during development of a positive resist by immersion lithography to obtain a fine pattern with a desired shape. Thus, the present invention is useful for a material for a barrier film formed on a resist film and a pattern formation method for use in, for example, fabrication of a semiconductor device.

What is claimed is:

1. A barrier film material for a barrier film formed between a positive chemically amplified resist film and a liquid in exposing the resist film to light with the liquid provided on the resist film, the barrier film material comprising:
a compound having an acid leaving group; and
a thermal acid generator.

2. The barrier film material of claim 1, wherein the acid leaving group is one of a t-butyl group, a 2-ethoxyethyl group, an adamanthyl group, and a t-butyloxycarbonyl group.

3. The barrier film material of claim 1, wherein the thermal acid generator is sulfonic acid ester whose ester moiety is an unsubstituted alkyl group.

4. The barrier film material of claim 3, wherein the sulfonic acid ester whose ester moiety is an unsubstituted alkyl group is one of cyclohexylbenzenesulfonic acid, t-butylbenzene sulfonic acid, cyclohexyl toluenesulfonic acid, and t-butyltoluenesulfonic acid.

5. A pattern formation method, comprising the steps of:
forming a positive chemically amplified resist film on a substrate;
performing pattern exposure by selectively irradiating the resist film with exposure light with a liquid provided on the resist film;
performing a surface process for making the surface of the resist film alkali-soluble, after the pattern exposure; and
developing the resist film subjected to the pattern exposure, thereby forming a resist pattern out of the resist film, after the surface process.

6. The pattern formation method of claim 5, wherein the step of performing the surface process includes the steps of:
exposing the resist film to a solution including a thermal acid generator; and
heating the resist film exposed to the solution including the thermal acid generator.

7. The pattern formation method of claim 6, wherein the thermal acid generator is sulfonic acid ester whose ester moiety is an unsubstituted alkyl group.

8. The pattern formation method of claim 7, wherein the sulfonic acid ester whose ester moiety is an unsubstituted alkyl group is one of cyclohexylbenzenesulfonic acid, t-butylbenzene sulfonic acid, cyclohexyl toluenesulfonic acid, and t-butyltoluenesulfonic acid.

9. The pattern formation method of claim 5, wherein the liquid is one of water and an acid solution.

10. The pattern formation method of claim 9, wherein the acid solution is one of a cesium sulfate aqueous solution and a phosphoric acid aqueous solution.

11. The pattern formation method of claim 5, wherein the exposure light is one of ArF excimer laser light, KrF excimer laser light, Xe₂ laser light, F₂ laser light, KrAr laser light, and Ar₂ laser light.

12. A pattern formation method, comprising the steps of:
forming a positive chemically amplified resist film on a substrate;
forming a barrier film including a compound having an acid leaving group and a thermal acid generator, on the resist film;
performing pattern exposure by selectively irradiating the resist film with exposure light through the barrier film with a liquid provided on the barrier film;
heating the resist film and the barrier film, after the pattern exposure;
removing the barrier film, after the step of heating the resist film and the barrier film; and
developing the resist film from which the barrier film has been removed, thereby forming a resist pattern out of the resist film.

13. The pattern formation method of claim 12, wherein the acid leaving group is one of a t-butyl group, a 2-ethoxyethyl group, an adamanthyl group, and a t-butyloxycarbonyl group.

14. The pattern formation method of claim 12, wherein the thermal acid generator is sulfonic acid ester whose ester moiety is an unsubstituted alkyl group.

15. The pattern formation method of claim 14, wherein the sulfonic acid ester whose ester moiety is an unsubstituted alkyl group is one of cyclohexylbenzenesulfonic acid, t-butylbenzene sulfonic acid, cyclohexyl toluenesulfonic acid, and t-butyltoluenesulfonic acid.

16. The pattern formation method of claim 12, further including the step of heating the barrier film, between the step of forming the barrier film and the step of performing the pattern exposure.

17. The pattern formation method of claim 12, wherein the liquid is one of water and an acid solution.

18. The pattern formation method of claim 17, wherein the acid solution is one of a cesium sulfate aqueous solution and a phosphoric acid aqueous solution.

19. The pattern formation method of claim 12, wherein the exposure light is one of ArF excimer laser light, KrF excimer laser light, Xe₂ laser light, F₂ laser light, KrAr laser light, and Ar₂ laser light.

20. A pattern formation method, comprising the steps of:
forming a positive chemically amplified resist film on a substrate;
forming a barrier film including a compound having an acid leaving group and a thermal acid generator, on the resist film;
performing pattern exposure by selectively irradiating the resist film with exposure light through the barrier film with a liquid provided on the barrier film;
heating the resist film and the barrier film, after the pattern exposure; and
developing the resist film subjected to the pattern exposure, thereby removing the barrier film and forming a resist pattern out of the resist film, after the step of heating the resist film and the barrier film.

21. The pattern formation method of claim 20, wherein the acid leaving group is one of a t-butyl group, a 2-ethoxyethyl group, an adamanthyl group, and a t-butyloxycarbonyl group.

22. The pattern formation method of claim 20, wherein the thermal acid generator is sulfonic acid ester whose ester moiety is an unsubstituted alkyl group.

23. The pattern formation method of claim 22, wherein the sulfonic acid ester whose ester moiety is an unsubstituted alkyl group is one of cyclohexylbenzenesulfonic acid, t-butylbenzene sulfonic acid, cyclohexyl toluenesulfonic acid, and t-butyltoluenesulfonic acid.

24. The pattern formation method of claim 20, further including the step of heating the barrier film, between the step of forming the barrier film and the step of performing the pattern exposure.

25. The pattern formation method of claim 20, wherein the liquid is one of water and an acid solution.

26. The pattern formation method of claim 25, wherein the acid solution is one of a cesium sulfate aqueous solution and a phosphoric acid aqueous solution.

27. The pattern formation method of claim 20, wherein the exposure light is one of ArF excimer laser light, KrF excimer laser light, Xe₂ laser light, F₂ laser light, KrAr laser light, and Ar₂ laser light.
